(19) United States
(12) Patent Application Publication
(10) Pub. No.: US 2009/0304112 A1
(43) Pub. Date: Dec. 10, 2009

(54) SCHEME TO ALLEVIATE SIGNAL DEGRADATION CAUSED BY DIGITAL GAIN CONTROL LOOPS

(75) Inventors: David Lomas, Wiltshire (GB); Stephan Ahles, Berkshire (GB)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 12/282,572

(22) PCT Filed: Mar. 12, 2007
(86) PCT No.: PCT/GB2007/000856

§ 371 Date: Feb. 12, 2009

(30) Foreign Application Priority Data
Mar. 13, 2006 (GB) 0605053.8

(51) Int. Cl. H04L 27/22; H04L 27/08; H03G 3/00

(52) U.S. Cl. 375/329; 375/345; 330/278

(57) ABSTRACT

An amplifier (10) comprises a digitally clocked automatic gain control loop (11, 12, 13, 14). A Pseudo random clock generator (14) generates the clock signals for the loop. The application introduces a scheme which reduces sidebands caused by digital gain control loops. The effect of gain control on a system can be seen as amplitude modulation on the signal whose amplitude is controlled. This amplitude modulation causes the same sidebands that are commonly seen with AM modulation. This invention introduces a novel method that alleviates AM sidebands for a digitally controlled gain control loop.

The present invention relates to amplifiers with automatic gain control.

It is particularly suitable for use in RF front end receiver type systems where the gain stages in the signal path are digitally programmable. The concept is, however, sufficiently general so that it could be used for any application where the gain of a signal path is switched digitally.

Digital automatic gain control (AGC) is a common concept used in many commercially available integrated circuit solutions such as mentioned in [2] and [3].

Patents relating to digital AGC can be found in refs [5] to [7].

An Automatic Gain Control (AGC) loop autonomously adjusts the gain of a system, so that it operates under optimal conditions for all possible signal powers within the system. An analogue AGC can control the gain of its system continuously, while a digital AGC adjusts the gain in discrete steps.

The problem with digitally controlled gain stages in signal paths is that they introduce amplitude modulation into the wanted signal, the level of which corresponds to the relative size of the discrete gain steps used. Due to the digital nature of the programmable gain path, the stable operating point may alternate about two adjacent gain settings. Every change in amplitude by the AGC will amplitude-modulate the signal, causing sidebands which in turn lead to an increase of in-band spurious signals. The reduction of the peak power of the AM sidebands is the main aim of the present invention.

The method proposed here introduces a clock with a pseudo-random clock period that is used instead of one with a fixed period. Using pseudo-random binary sequence generators is a concept which has been used for the spreading of spectral power in many applications like fractional-N PLLs ([4], [5]). However, the application of a pseudo-random clock on an AGC, is a new concept that is introduced here.

The generation of a pseudo-random binary sequence (PRBS) using a linear-feedback shift-register (LFSR) is also common knowledge and is e.g. referred to in [1].

The preferred embodiment of the invention includes a digitally clocked Automatic Gain Control (AGC) loop utilising a Pseudo Random Binary (PRBS) clock. The purpose of the PRBS clock is to spread the energy of any signal sidebands that are formed in the signal path due to switching the gain in discrete steps.

For most applications the PRBS clock should have an average clock rate sufficient to maintain the required AGC loop gain bandwidth product, but the random variation of the clock edge due to the PRBS sequence causes the power of the signal sidebands, due to gain modulation, to be spread such that their peak values are at a much lower level.

This reduces the peak levels of the interference experienced by the wanted signal, causing the AM sidebands to appear more as an increase in the white noise floor. This is a very important factor for multi-carrier modulation schemes.

An embodiment of the invention will now be described by way of example only and with reference to the accompanying drawings which:

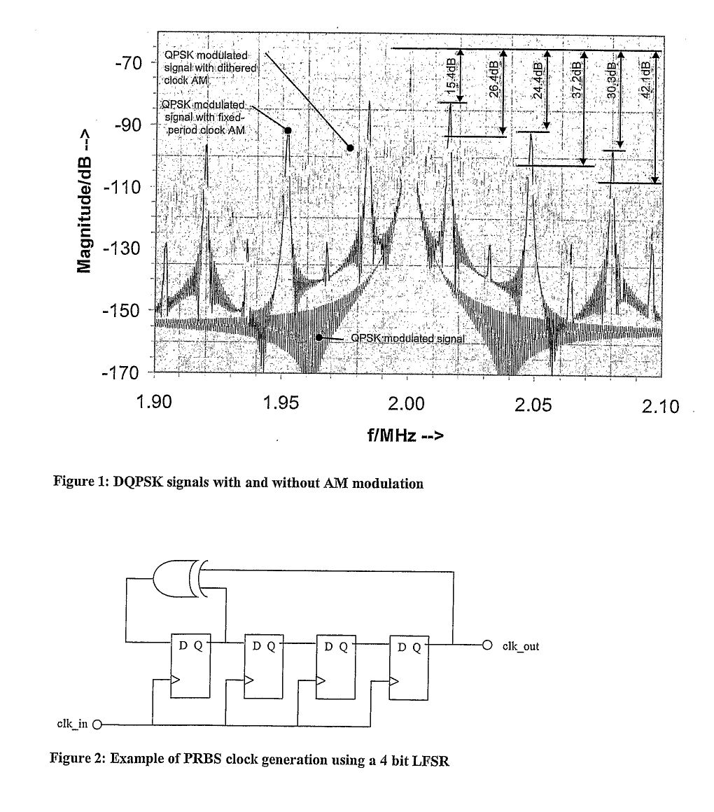

FIG. 1 shows three overlaid spectra of QPSK modulated signals to illustrate the effect of the invention;

FIG. 2 shows a 4 bit LFSR which can be used to generate a PRBS clock; and

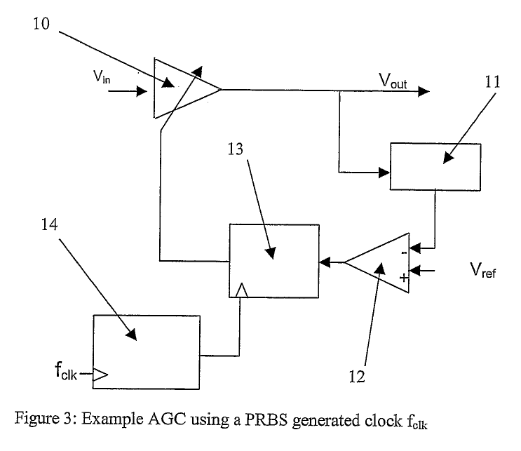

FIG. 3 shows a typical AGC control loop which can be used with a dithered clock.

A typical AGC loop together with the block it controls is shown in FIG. 3. Incoming RF signals are input to analogue amplifier 10. Although a single amplifier is shown, this could be replaced by two or more in parallel. The amplified voltage output from amplifier 10 is used in a feed back loop including received signal strength indication (RSSI) detector 11, comparator 12 and integrator 13.

The output of the detector 11 will vary with the input RF signal level and is a continuously varying analogue voltage. This is compared to a reference value in comparator 12 whose output is supplied to integrator 13. The integrator will typically include a digital up/down counter and digital to analogue converter and will output a digitised (i.e: stepwise varying) gain control signal to the input amplifier 10.

Integrator 13 is clocked using a pseudo random clock generator 14 preferably in the form of a linear feedback shift register as shown in FIG. 2.

This example is taken from an RF receiver. The gain control loop in this example is partly digital and therefore needs a clock input.

If this clock has a fixed frequency, the actions of the AGC can appear as AM modulation on the received signal. The signal spectras shown in FIG. 1 illustrate this. First, it shows the spectrum of a QPSK signal. The second spectrum is that of a QPSK signal, which is also AM modulated with 4 dB step size and a fixed-period 16 kHz clock. The third spectrum was obtained by using a dithered clock to AM-modulate the QPSK signal. The dithered clock was generated by a 15 bit LFSR. It can be seen that, using this method, the power of the sidebands is reduced considerably. The average clocking frequency of the PRBS clock was approximately equal to that of the undithered clock.

Please note that a 4 bit LFSR is not sufficient to produce a truly random clock. For our investigations, we actually used a 15 bit LFSR. The circuit shown in FIG. 2 is only an illustration of the technique.

QPSK modulation was chosen in this example as the target application was DAB, which uses OFDM and DQPSK as the modulation scheme. 15 bit was chosen as this generates a sufficiently random clock combined with the advantage of a simple implementation. Apart from 15 D-FFs, only a two-input XOR gate is required.

It can be seen that the AM modulation causes sidebands. However, these sidebands can be reduced using a dithered clock. As shown in the graph, the reduction in the peak sideband power is achieved by spreading the power of the sideband over a larger frequency range. The sidebands simply appear as an increase in the noise floor. The reduction of peak sideband power improves with increasing complexity LFSR, up to around 50 bits.

As mentioned earlier, the concept introduced here, can be used for any system where a gain of a system is adjusted digitally by a control loop. The main application of the invention is RF receiver systems but other applications like gain adjustment in digital cameras, or audio volume control could be found.

### REFERENCES

[1] David Green, “Modern Logic Design” 1986, Addison-Wesley Publishing Company, pages 182 ff.
[2] Maxim RF transceivers MAX×2825, MAX2826, MAX2827. REM RE receiver RX5000.
[3] Asad A. Abidi, “RF CMOS Comes of Age”, IEEE JOURNAL OF SOLID-STATE CIRCUITS, VOL. 39, NO. 4.
[4] T. A. D. Riley, M. A. Copeland, and T. A. Kwasniewski, “Delta-sigma modulation in fractional-N frequency synthesis,” IEEE J. Solid-State Circuits, vol. 28, pp. 553-559, May 1993,
[5] Chambers, Ramon P./Sanders, David E./Gordy, Robert S., U.S. Pat. No. 4,066,977 A
[6] Bongfeldt, David, U.S. Pat. No. 6,889,033 B2
Sidman, Michael D., U.S. Pat. No. 5,220,468 A

1. An amplifier having a digital automatic gain control loop in which the gain control circuitry is clocked using a dithered clock signal.

2. An amplifier as claimed in claim 1 in which the clock signal is derived from a pseudo-random binary sequence.

3. An amplifier as claimed in claims 1 or 2 in which the clock signal maintains an average clock frequency over a predetermined period.

4. An amplifier as claimed in claim 1 or 2 in which the clock signal is derived from a linear feedback shift register.

5. An amplifier as claimed in claim 1 or 2 in which the signal input to the automatic gain control is a continuously variable analogue signal.

6. A radio receiver having an amplifier as claimed in 1 or 2 claim.

7. A radio receiver as claimed in claim 6 in which the amplifier is a the radio frequency front end.

8. A radio receiver as claimed in claim 7 in which the gain control signal is derived from the received signal strength indication.

9. A radio receiver as claimed in claim 6 having means for receiving and reproducing digital audio broadcast signals, in which, in use, the signals applied to the amplifier are encoded using phase shift keying.
